(19) United States
(12) Patent Application Publication
(10) Pub. No.: US 2006/0043427 A1
(43) Pub. Date: Mar. 2, 2006

(54) Automatic-arrangement-wiring apparatus for and program for performing layout of integrated circuit

(75) Inventors: Michio Komoda, Tokyo (JP); Kanako Yoshida, Tokyo (JP)

Correspondence Address: BUCHANAN INGERSOLL PC;(INCLUDING BURNS, DOANE, SWECKER & MATHIS), POST OFFICE BOX 1404, ALEXANDRIA, VA, 22313-1404, US

(73) Assignee: Renesas Technology Corp., Tokyo (JP)

(21) Appl. No.: 11/205,149

(22) Filed: Aug. 17, 2005

(30) Foreign Application Priority Data
Aug. 27, 2004 (JP) 2004-248912

(51) Int. Cl. H01L 27/10

(52) U.S. Cl. 257/210

(57) ABSTRACT

An automatic-arrangement-wiring apparatus is provided with a calculating unit for calculating the lowest transfer rate and a corresponding repeater-to-repeater distance for each of wiring layers having different time constants, an arrangement unit or carrying out automatic arrangement, an estimating unit for estimating the wire length of each of wiring routes based on arrangement results, another calculating unit for calculating a transfer rate threshold required of each wiring route whose wire length is equal to or longer than a wire length threshold specified by the user from a propagation delay and the estimated wire length, an assigning unit for assigning a wiring layer having the highest transfer rate among selected wiring layers to each wiring route in question, a repeater inserting unit for inserting one or more repeaters into each wiring route in question, and a wiring processing unit for performing automatic wiring.

### BACKGROUND OF THE INVENTION

1. Field of the Invention

The present invention relates to an automatic-arrangement-wiring apparatus that performs layout of an integrated circuit, and a program which causes a computer to implement the functions of the automatic-arrangement-wiring apparatus.

2. Description of Related Art

In accordance with a related art method of performing layout of an integrated circuit which has been conventionally used, a timing verification program is executed for a layout in which automatic arrangement wiring is completed, and, if a timing error part exists in long-distance wiring of the layout, a functional block or a macro cell in which the timing error occurs is specified based on a timing error path associated with the timing error, wide wiring (i.e., low time constant wiring) is selected for the long-distance wiring, and layout wiring is carried out again. For this reason, it is necessary to repeat layout wiring and timing verification by trial and error two or more times until no timing error part is identified, and therefore much time cannot but be spent on layout design.

On the other hand, in accordance with a related art layout method disclosed by, for example, patent reference 1, after automatic arrangement of components is carried out, outline wiring is carried out and a timing verification program is executed so that a net delay value is checked for every wiring layer which can implement a net, or every set of wiring layers, using a wiring route determined by the outline routing. By carrying out assignment of sets of wiring layers which are used for detailed routing according to results of the checking, the assignment of wiring layers can be efficiently carried out in consideration of timing without repeating automatic arrangement wiring and timing verification two or more times until no timing error part is identified.

[Patent reference 1] JP,7-325855,A

In accordance with the related art layout method disclosed by patent reference 1, while assignment of wiring layers can be efficiently carried out in consideration of wire delays based on results of checking the net delay values of the wiring layers, any insertion arrangement of repeaters at predetermined intervals of a distance which provides the lowest transfer rate is not carried out in consideration of the time constants of the wiring layers and wiring resources so as to further improve the efficiency of the assignment of the wiring layers.

### SUMMARY OF THE INVENTION

The present invention is made in order to solve the above-mentioned problems, and it is therefore an object of the present invention to provide an automatic-arrangement-wiring apparatus that can carry out the design of a semiconductor integrated circuit having appropriate timings by carrying out automatic arrangement wiring only one time without repeating the automatic arrangement wiring and timing verification two or more times until no timing error part is identified, and that can carry out assignment of wiring layers efficiently at the arrangement stage and afterward in consideration of the time constants of the wiring layers and wiring resources, and a program which makes a computer carry out the functions of the automatic-arrangement-wiring apparatus.

In accordance with the present invention, there is provided an automatic-arrangement-wiring apparatus including a transfer rate and repeater-to-repeater distance calculating unit for calculating the lowest transfer rate and a corresponding repeater-to-repeater distance for each of a plurality of wiring layers having different time constants based on a relationship between a repeater-to-repeater distance and a transfer rate for each of the plurality of wiring layers, an arrangement processing unit for carrying out automatic arrangement of cells of an integrated circuit which is a target of layout based on a netlist, a wire-length estimating unit for estimating the wire length of each of wiring routes which are disposed among the automatically-arranged cells based on arrangement results obtained by the arrangement processing unit, a wire-length determining unit for determining whether or not the wire length of each of the wiring routes estimated by the wire-length estimating unit is equal to or longer than a wire length threshold specified by the user, a transfer rate calculating unit for estimating a propagation delay which occurs in each wiring route whose wire length is equal to or longer than the wire length threshold specified by the user based on a timing limit condition provided to each wiring route in question, and for calculating a transfer rate threshold required of each wiring route in question from the estimated delay and the wire length estimated by the wire-length estimating unit, a wiring layer assigning unit for selecting wiring layers whose lowest transfer rates calculated by the transfer rate and repeater-to-repeater distance calculating unit do not exceed the transfer rate threshold calculated by the transfer rate calculating unit from among the plurality of wiring layers, and for assigning a wiring layer having the highest transfer rate among the selected wiring layers to each wiring route in question, a repeater inserting unit for determining a repeater-to-repeater distance which minimizes the transfer rate of a wiring layer which is assigned to each wiring route whose wire length is equal to or longer than the wire length threshold by the wiring layer assigning unit by using a relationship between the lowest transfer rate and the corresponding repeater-to-repeater distance, which is obtained by the transfer rate and repeater-to-repeater distance calculating unit, and for arranging one or more repeaters at one or more positions defined by the repeater-to-repeater distance on each wiring route in question, and a wiring processing unit for performing automatic wiring on both wiring layers, which are assigned to wiring routes whose wire lengths are equal to or longer than the wire length threshold by the wiring layer assigning unit, and wiring routes whose wire lengths are determined to be shorter than the wire length threshold by the wire-length determining unit.

Therefore, the automatic-arrangement-wiring apparatus can provide layout of a semiconductor integrated circuit having appropriate timings by carrying out automatic arrangement wiring only one time without repeating the automatic arrangement wiring and timing verification two or more times until no timing error part is identified, and can carry out of assignment of wiring layers efficiently at the arrangement stage and afterward in consideration of the time constants of the wiring layers and wiring resources.

Further objects and advantages of the present invention will be apparent from the following description of the preferred embodiments of the invention as illustrated in the accompanying drawings.

### BRIEF DESCRIPTION OF THE DRAWINGS

FIG. 1 is a diagram showing an example of the outward appearance of a computer apparatus which embodies an automatic-arrangement-wiring apparatus according to embodiment 1 of the present invention;

FIG. 2 is a diagram showing the structure of the computer apparatus shown in FIG. 1;

FIG. 3 is a block diagram showing the structure of the automatic-arrangement-wiring apparatus according to embodiment 1 of the present invention;

FIG. 4 is a diagram explaining a relationship between a repeater-to-repeater distance and a delay time;

FIG. 5 is a flow chart showing the operation of the automatic-arrangement-wiring apparatus in accordance with this embodiment 1;

FIG. 6 is a graph showing a relationship among the repeater-to-repeater distance, a transfer rate, and the delay time; and

FIG. 7 is a graph showing the lowest transfer rate which is provided for the time constant of each of a plurality of wiring layers.

### DETAILED DESCRIPTION OF THE PREFERRED EMBODIMENTS

Embodiment 1.

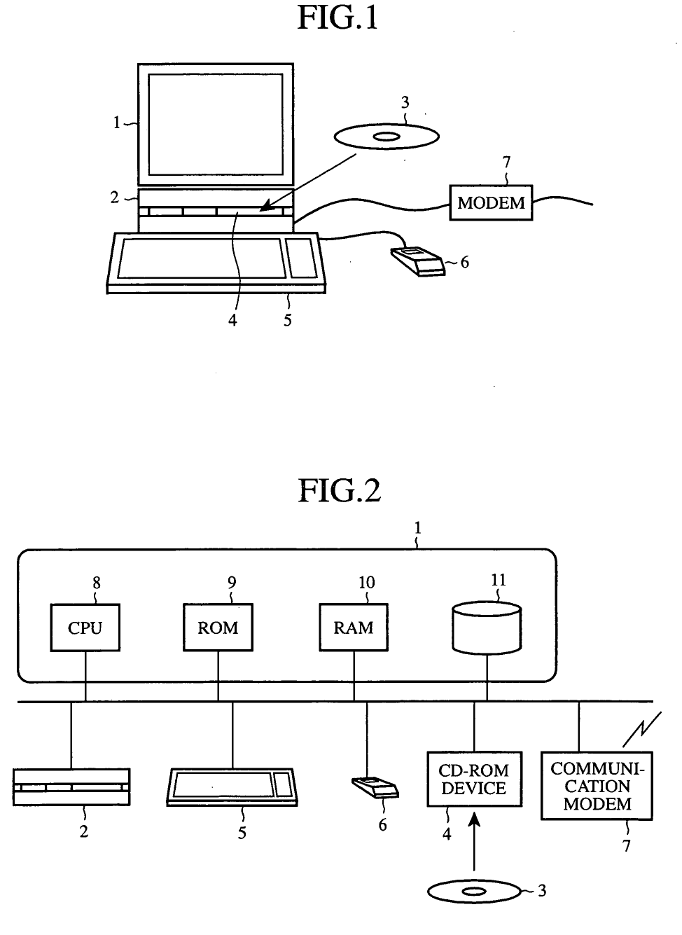

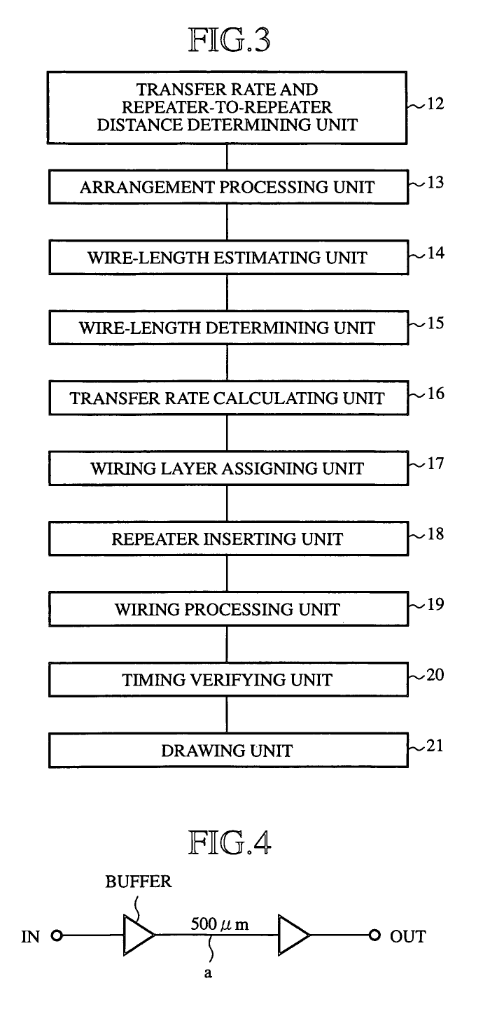

FIG. 1 is a diagram showing an example of the outward appearance of a computer apparatus which embodies an automatic-arrangement-wiring apparatus according to embodiment 1 of the present invention, and FIG. 2 is a diagram showing the structure of the computer apparatus shown in FIG. 1. FIG. 3 is a block diagram showing the structure of the automatic-arrangement-wiring apparatus according to embodiment 1 of the present invention. As shown in the example of FIG. 1, the computer apparatus which embodies the automatic-arrangement-wiring apparatus according to embodiment 1 of the present invention is provided with a main unit 1, a graphic display device 2, a CD-ROM (Compact Disk-Read Only Memory) 3, a CD-ROM drive device 4, a keyboard 5, a mouse 6, and a communication modem 7.

A layout processing program used for layout of integrated circuits which falls within the scope of the present invention is loaded into the above-mentioned computer apparatus via either a storage medium, such as the CD-ROM 3, or net distribution using the communication modem 7. This layout processing program used for layout of integrated circuits is executed by the main unit 1. Looking at results of execution of an automatic-arrangement-wiring program, which are displayed on the graphic display device 2, the user can manipulate an input device, such as the keyboard 5 or mouse 6, to input required parameter values etc. into the computer apparatus, and to cause the layout processing program to carry out a layout of a desired integrated circuit.

The main unit 1 is provided with a CPU 8, a ROM (Read Only Memory) 9, a RAM (Random Access Memory) 10, and a hard disk drive unit 11, as shown in the example of FIG. 2. The CPU 8 carries out data processing while exchanging data between any two of the graphic display device 2, CD-ROM drive device 4, keyboard 5, mouse 6, communication modem 7, ROM 9, RAM 10, and hard disk drive unit 11.

The layout processing program used for layout of integrated circuits which is recorded in the storage medium, such as the CD-ROM 3, is stored from the CD-ROM drive device 4 into the hard disk drive unit 11 by the CPU 8. The CPU 8 executes the layout processing program according to the present invention which is loaded thereinto from the hard disk drive unit 11 when deemed appropriate, and displays layout processing results on the graphic display device 2 if needed.

The automatic-arrangement-wiring apparatus according to embodiment 1 of the present invention is provided with a transfer rate and repeater-to-repeater distance determining unit (i.e., a transfer rate/repeater-to-repeater distance calculating unit) 12, an arrangement processing unit 13, a wire-length estimating unit 14, a wire-length determining unit 15, a transfer rate calculating unit 16, a wiring layer assigning unit 17, a repeater inserting unit 18, a wiring processing unit 19, a timing verifying unit 20, and a drawing unit 21. These components 12 to 21 can be implemented, as functional modules, via the layout processing program used for layout of integrated circuits according to the present invention.

In other words, the transfer rate repeater-to-repeater distance determining unit 12, arrangement processing unit 13, wire-length estimating unit 14, wire-length determining unit 15, transfer rate calculating unit 16, wiring layer assigning unit 17, repeater inserting unit 18, wiring processing unit 19, timing verifying unit 20, and drawing unit 21 can be embodied by carrying out the layout processing program used for layout of integrated circuits according to the present invention using, for example, the general-purpose computer as shown in FIG. 1.

To be more specific, the layout processing program used for layout of integrated circuits according to the present invention is loaded into the computer, and the operation of the computer is controlled by the layout processing program so that the transfer rate repeater-to-repeater distance determining unit 12, arrangement processing unit 13, wire-length estimating unit 14, wire-length determining unit 15, transfer rate calculating unit 16, wiring layer assigning unit 17, repeater inserting unit 18, wiring processing unit 19, timing verifying unit 20, and drawing unit 21, which are shown in FIG. 3, can be implemented on the computer.

The transfer rate and repeater-to-repeater distance determining unit 12 acquires a relationship between a repeater-to-repeater distance and a transfer rate for each of a plurality of wiring layers having different time constants based on a relationship between the repeater-to-repeater distance and a propagation delay which is prepared beforehand for each of the plurality of wiring layers, and calculates the lowest transfer rate for each of the plurality of wiring layers. For a wiring layer which connects between two adjacent repeaters, the transfer rate (which is also called propagation time) is the time required for signals to propagate over a unit length of the wiring layer, and is therefore expressed in units of time per unit length. In accordance with the present invention, the fact that a wiring layer which connects between two adjacent repeaters has a low transfer rate shows that the time required for signals to propagate over a unit distance of the wiring layer is short, whereas the fact that the wiring layer has a high transfer rate shows that the time required for signals to propagate over a unit length of the wiring layer is long.

For a wiring layer, the propagation delay is the time required for signals to propagate between two adjacent repeaters in the wiring layer, and the repeater-to-repeater distance is the distance between two adjacent repeaters in the wiring layer. In accordance with this embodiment, each repeater's own delay is disregarded and the result of division of the propagation delay by the repeater-to-repeater distance is acquired as the transfer rate associated with this repeater-to-repeater distance.

For example, as shown in FIG. 4, assume that two buffers which are repeaters are connected in series by a wiring layer a having a time constant, and the distance between the two buffers (i.e., repeaters) is equal to 500 μm. At this time, since each repeater's own delay is disregarded, the time required for a signal inputted into one of the buffers via an input IN to reach an output OUT is equal to the propagation delay associated with the repeater-to-repeater distance of 500 μm in the wiring layer a having a time constant.

A relationship between the repeater-to-repeater distance and the corresponding propagation delay for each of the plurality of wiring layers is determined by varying the repeater-to-repeater distance for the time constant of each of the plurality of wiring layers so as to determine the corresponding propagation delay successively. The information about this relationship is pre-stored in the hard disk drive unit 11 as electronized table data.

Measurement of the propagation delay can be carried out by making the transfer rate and repeater-to-repeater distance determining unit 12 operate as a delay calculating engine, and making the automatic-arrangement-wiring apparatus according to the present invention operate automatically. As an alternative, circuit simulation can be carried out beforehand to determine the corresponding propagation delay for the varying repeater-to-repeater distance, or an actual measurement of the propagation delay can be used.

The arrangement processing unit 13 carries out arrangement of blocks and macro cells within the layout of the target integrated circuit. The wire-length estimating unit 14 estimates the length of each of a plurality of wiring routes based on the arrangement results obtained by the arrangement processing unit 13. The wire-length determining unit 15 compares the estimated length of each of the plurality of wiring routes with a wire length threshold specified by the user to determine whether or not the estimated length is equal to or longer than the wire length threshold. For each of the plurality of wiring routes, the transfer rate calculating unit 16 calculates a transfer rate threshold by estimating a required propagation delay from timing values for the wire length threshold specified by the user.

For each of the plurality of wiring routes, the wiring layer assigning unit 17 then compares the transfer rate threshold calculated by the transfer rate calculating unit 16 with the lowest transfer rates which are respectively acquired for the plurality of wiring layers having different time constants by the transfer rate and repeater-to-repeater distance determining unit 12, and selects and assigns a wiring layer having the highest transfer rate from among wiring layers having transfer rates which do not exceed the transfer rate threshold calculated by the transfer rate calculating unit 16 to each wiring route in question. The repeater inserting unit 18 determines positions where repeaters should be inserted in the wiring pattern of the wiring layer which is assigned to each of the plurality of wiring routes based on the transfer rate of the wiring layer and the estimated wire length of each of the plurality of wiring routes, and carries out arrangement of repeaters. The wiring processing unit 19 performs wiring processing on the wiring layer which is assigned to each of the plurality of wiring routes by the wiring layer assigning unit 17.

The timing verifying unit 20 verifies whether the result of the layout of the automatic arrangement wiring carried out by the arrangement processing unit 13 and wiring processing unit 19 satisfies timings specified by the user. The timing verifying unit 20 can be embodied by another computer, and can be constructed as to carry out the verifying processing in synchronization with the automatic-arrangement-wiring apparatus according to the present invention.

The drawing unit 21 displays the result of the layout of the automatic arrangement wiring carried out by the arrangement processing unit 13 and wiring processing unit 19 on the display screen of the graphic display device 2. The drawing unit 21 offers a GUI (Graphical User Interface) for displaying an input window used for accepting parameters, such as the length of each of the plurality of wiring routes and timing information about timings of each of the plurality of wiring routes, required for the automatic arrangement wiring and inputted by the user using an input device, such as the keyboard 5 or mouse 6, etc. on the display screen of the graphic display device 2 as appropriate.

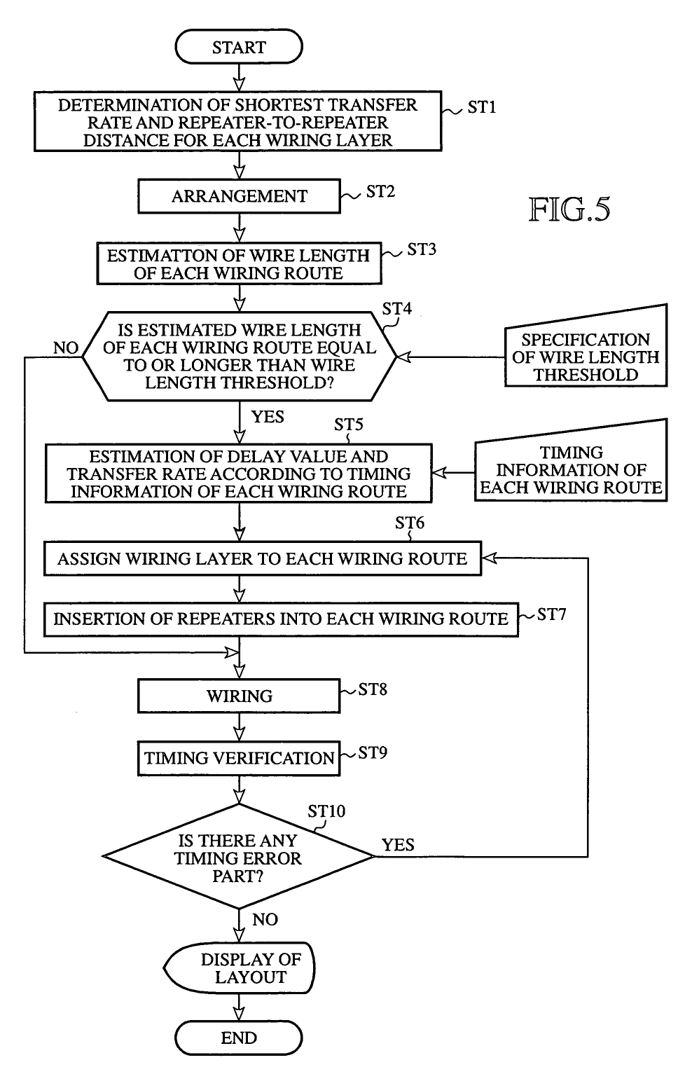

Next, the operation of the automatic-arrangement-wiring apparatus in accordance with this embodiment of the present invention will be explained. FIG. 5 is a flow chart showing the operation of the automatic-arrangement-wiring apparatus according to embodiment 1. The automatic-arrangement-wiring apparatus will be explained with reference to this diagram.

First, before carrying out layout wiring, the transfer rate and repeater-to-repeater distance determining unit 12 reads electronic data indicating a relationship between the repeater-to-repeater distance and the propagation delay which is predetermined for each of a plurality of wiring layers having different time constants from the hard disk drive unit 11, and writes the electronic data into the RAM 10. The transfer rate and repeater-to-repeater distance determining unit 12 then calculates a transfer rate for each of the plurality of wiring layers from the relationship between the repeater-to-repeater distance and the propagation delay indicated by the electronic data, and acquires a relationship between the repeater-to-repeater distance and the transfer rate for each of the plurality of wiring layers. The transfer rate and repeater-to-repeater distance determining unit 12 then calculates the lowest transfer rate for each of the plurality of wiring layers having different time constants from the relationship between the repeater-to-repeater distance and the transfer rate.

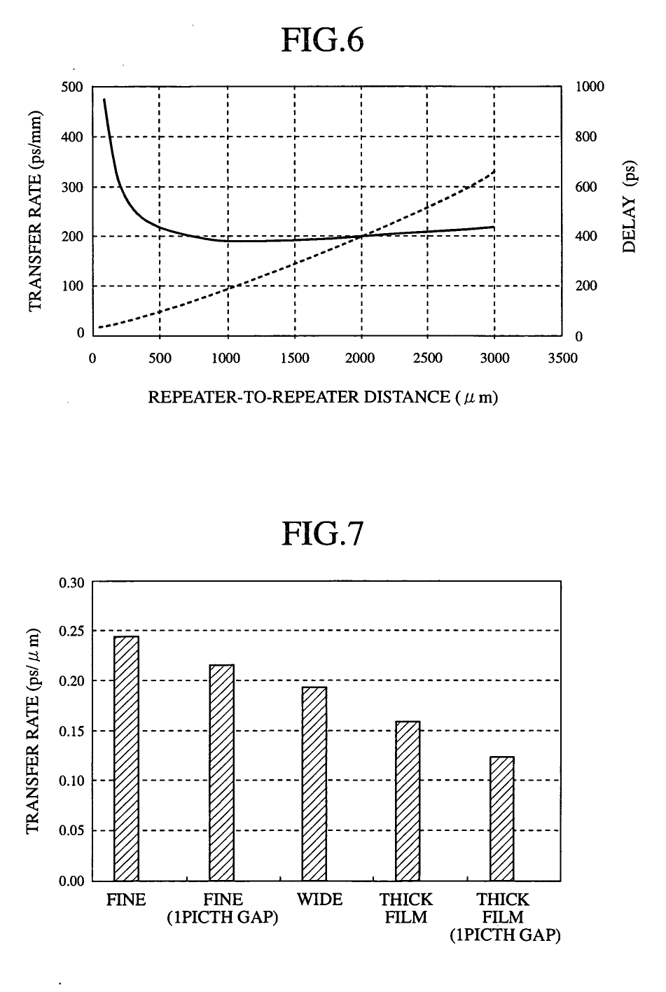

FIG. 6 is a graph showing both the relationship between the repeater-to-repeater distance and the propagation delay and the relationship between the repeater-to-repeater distance and the transfer rate which are provided for a certain wiring layer. A concrete calculation method of calculating the lowest transfer rate will be explained with reference to this diagram. A curve of a dashed line in the diagram shows the relationship between the repeater-to-repeater distance and the propagation delay. A curve of a solid line in the diagram indicating the transfer rate (ps/mm) is acquired by dividing the propagation delay (ps) by the corresponding repeater-to-repeater distance (μm=10⁻³ mm). A minimum value of the transfer rate indicated by this curve of a solid line is the lowest transfer rate. The lowest transfer rate is calculated according to the time constant of the wiring layer which is determined by the transfer rate and repeater-to-repeater distance determining unit 12 based on the width and film thickness of the wiring layer, etc.

Electronic information about the transfer rate, repeater-to-repeater distance, and propagation delay which are determined in this way is stored in the RAM 10 by the transfer rate and repeater-to-repeater distance determining unit 12. The processing which is explained up to now corresponds to step ST1.

The arrangement processing unit 13 then carries out arrangement of blocks and macro cells using a netlist which defines a connection relationship among blocks and macro cells in each desired logical circuit within the target semiconductor integrated circuit (in step ST2). Either of various types of arrangement technologies existing at the time of the application of the present invention can be used as this arrangement technique.

When the arrangement of blocks and macro cells in the target semiconductor integrated circuit is completed, the wire-length estimating unit 14 estimates the wire length of each of wiring routes which are to be provided among the blocks and macro cells arranged in the target semiconductor integrated circuit based on the results of the arrangement (in step ST3). Using a conventional technology using a Manhattan distance or the like, which is existing at the time of the application of the present invention, as a method of estimating the wire length, the wire-length estimating unit 14 estimates the wire length of each of the wiring routes in consideration of the congestion degree and degree of difficulty of wiring according to the arrangement results.

When accepting information about the estimated wire length from the wire-length estimating unit 14, the wire-length determining unit 15 compares this information about the estimated wire length with information about the wire length threshold specified by the user, and determines whether or not the estimated wire length is equal to or longer than the wire length threshold specified by the user (in step ST4). The wire length threshold specified by the user is a wire length which provides a maximum permissible propagation delay according to the specifications of the semiconductor integrated circuit. The user inputs the information on this wire length threshold specified thereby into the automatic-arrangement-wiring apparatus according to this embodiment by using an input device, such as the keyboard 5 or mouse 6.

In step ST4, when the wire length estimated by the wire-length estimating unit 14 is shorter than the wire length threshold specified by the user, the automatic-arrangement-wiring apparatus shifts to wiring processing of step ST8. On the other hand, when determining that the estimated wiring length is equal to or longer than the wire length threshold specified by the user, the wire-length estimating unit 14 outputs the fact that the estimated wiring length is equal to or longer than the wire length threshold specified by the user and the information about the estimated wiring length to the transfer rate calculating unit 16.

The transfer rate calculating unit 16 then estimates a propagation delay which occurs in each wiring route whose wire length is equal to or longer than the wire length threshold specified by the user based on a timing limit value provided to the estimated wire length of each wiring route in question, and for calculating a transfer rate threshold required of each wiring route in question from the estimated delay and the wire length estimated by the wire-length estimating unit 14 (in step ST5). The timing value specified by the user and provided to the wire length of each wiring route which is determined to be equal to or longer than the wire length threshold is a timing limit for the wire length of each wiring route in question which the user has specified according to the specifications of the semiconductor integrated circuit. For example, the timing value can be a real wire capacitance. The user inputs the timing value into the automatic-arrangement-wiring apparatus according to this embodiment by using an input device, such as the keyboard 5 or mouse 6.

For example, when the estimated wire length of wiring which connects between two certain blocks is 2 mm, and it is estimated that the time period (i.e., the propagation delay) within which signals must be transmitted between the two blocks is 400 ps based on the timing value which is specified by the user for the wiring, the required transfer rate of the wiring which connects between the two blocks is 400/(2×10³)=0.20 ps/μm.

The information about the transfer rate threshold and propagation delay which are determined for the estimated wire length of each wiring route which is determined to be equal to or longer than the wire length threshold specified by the user is outputted from the transfer rate calculating unit 16 to the wiring layer assigning unit 17. The wiring layer assigning unit 17 then compares the transfer rate threshold calculated by the transfer rate calculating unit 16 with the lowest transfer rates which are respectively predetermined for the plurality of wiring layers having different time constants, and selects and assigns a wiring layer having the highest transfer rate from among wiring layers whose lowest transfer rates do not exceed the transfer rate threshold calculated by the transfer rate calculating unit 16 to each wiring route in question (in step ST6).

The above-mentioned processing will be explained using a specific example. A case where a required transfer rate of wiring which connects between two blocks, which is calculated by the transfer rate calculating unit 16, is equal to 400/(2×10³)=0.20 ps/mum, as mentioned above, on the condition that the estimated wire length is 2 mm and the time period within which signals must be transmitted between the two blocks is 400 ps will be explained as an example.

FIG. 7 is a graph showing an example of the lowest transfer rates which are respectively calculated beforehand for the plurality of wiring layers having different time constants by the transfer rate and repeater-to-repeater distance determining unit 12. In the figure, FINE shows a fine wiring layer having a circuit pattern of a thinner width than that of a wide wiring layer which will be mentioned below, and a transfer rate is acquired assuming that wiring is carried out at intervals of a fixed pitch in this case. In a case of FINE (1Pitch gap), a transfer rate is acquired assuming that a gap having the same width as the above-mentioned constant pitch between two adjacent FINE wiring layers is further provided in addition to the constant pitch.

In FIG. 7, WIDE shows a wiring layer having a circuit pattern of a wider wiring width than that of a FINE wiring layer, and a transfer rate is acquired assuming that wiring is carried out at intervals of the above-mentioned fixed pitch in this case. Furthermore, THICK FILM shows a wiring layer having a circuit pattern of a wider wiring width than that of a FINE wiring layer, and a transfer rate is acquired assuming that wiring is carried out at intervals of the above-mentioned fixed pitch in this case. In a case of THICK FILM (1Pitch gap), a transfer rate is acquired assuming that a gap having the same width as the above-mentioned constant pitch between two adjacent thick film wiring layers is further provided in addition to the constant pitch.

For example, the transfer rate for FINE wiring layer is 0.248 ps/μm, and the transfer rate for THICK FILM (1Pitch gap) wiring layer is 0.130 ps/μm. That is, the time required for signals to propagate through a THICK FILM (1Pitch gap) wiring layer having a length of 1 μm is 0.130 ps, whereas the time required for signals to propagate through a FINE wiring layer having a length of 1 μm is 0.248 ps, and the FINE wiring layer makes signals propagate therethrough more slowly than those propagating through the THICK FILM (1Pitch gap) wiring layer. When the transfer rate calculated by the transfer rate calculating unit 16 for the estimated wiring length which is equal to or longer than the wire length threshold specified by the user is 0.20 ps/μm, the wiring layer assigning unit 17 selects the WIDE wiring layer, THICK FILM wiring layer, THICK FILM (1Pitch gap) wiring layer which are wiring layers whose transfer rates do not exceed 0.20 ps/μm from among the wiring layers shown in the graph of FIG. 7, and then assigns the WIDE wiring layer having the highest transfer rate of the selected wiring layers to the wiring route in question.

The repeater inserting unit 18 then uses the relationship between the repeater-to-repeater distance and the transfer rate, as shown in FIG. 6, which is predetermined by the transfer rate and repeater-to-repeater distance determining unit 12, so as to determine a repeater-to-repeater distance which minimizes the transfer rate of the wiring layer which is assigned to each wiring route in question by the wiring layer assigning unit 17. The repeater inserting unit 18 further compares the wire length of each wiring route in question with the repeater-to-repeater distance determined as mentioned above, and, when the wire length of each wiring route in question is longer than the determined repeater-to-repeater distance, inserts one or more repeaters, such as buffers, into each wiring route in question formed of the assigned wiring layer at intervals specified by the repeater-to-repeater distance (in step ST7).

When the wire-length determining unit 15, in step ST4, determines that the estimated wiring length is shorter than the wire length threshold specified by the user, or when the processing up to above-mentioned step ST7 is completed, the wiring processing unit 19 performs wiring processing on each of the plurality of wiring routes having an estimated wiring length, and also performs wiring processing on the wiring layer which is assigned to each wiring route by the wiring layer assigning unit 17 (in step ST8). At this time, the automatic arrangement wiring apparatus performs this processing on the plurality of wiring routes in decreasing order of transfer rates required of wiring layers which are assigned to the plurality of wiring routes, respectively. As a result, wiring can be sequentially performed on the wiring layers in order of decreasing time constant and hence decreasing transfer rate, but decreasing number of wiring resources, a fine wiring layer with the largest time constant and hence the highest transfer rate, but the largest number of wiring resources first. Therefore, automatic wiring with a good efficiency in consideration of the wiring resources can be implemented.

The timing verifying unit 20 then performs timing verification on the automatically-arranged wiring layout which is thus obtained as mentioned above (in step ST9), and determines whether timing error parts exist in the automatically-arranged wiring layout (in step ST10). When determining that timing error parts exist in the automatically-arranged wiring layout, the automatic-arrangement-wiring apparatus returns to the process of step ST6 in which it carries out assignment of wiring layers to the plurality of wiring routes again.

For example, the wiring layer assigning unit 17 assigns a wiring layer having the second highest transfer rate, which is selected from among wiring layers whose transfer rates do not exceed the transfer rate threshold calculated by the transfer rate calculating unit 16 based on the relationship between the plurality of wiring layers as shown in FIG. 7 and their lowest transfer rates, to each of the plurality of wiring routes. Then, wiring is sequentially performed on the wiring layers in order of decreasing time constant and hence decreasing transfer rate, but decreasing number of wiring resources,

On the other hand, when determining that no timing error part exists in the automatically-arranged wiring layout, the timing verifying unit 20 notifies the fact to the drawing unit 21. As a result, the drawing unit 21 displays the layout created as mentioned above of the target semiconductor integrated circuit on the display screen of the graphic display device 2 to provide it for the user.

As mentioned above, the automatic-arrangement-wiring apparatus according to this embodiment 1 includes the transfer rate and repeater-to-repeater distance calculating unit 12 for calculating the lowest transfer rate and a corresponding repeater-to-repeater distance based on a relationship between a repeater-to-repeater distance and a transfer rate for each of a plurality of wiring layers having different time constants, the arrangement processing unit 13 for carrying out automatic arrangement of cells of an integrated circuit which is a target of layout based on a netlist, the wire-length estimating unit 14 for estimating the wire length of each of wiring routes which are disposed among the automatically-arranged cells based on arrangement results obtained by the arrangement processing unit 13, the wire-length determining unit 15 for determining whether or not the wire length of each of the wiring routes estimated by the wire-length estimating unit 14 is equal to or longer than a wire length threshold specified by the user, the transfer rate calculating unit 16 for estimating a propagation delay which occurs in each wiring route whose wire length is equal to or longer than the wire length threshold specified by the user based on a timing limit condition provided to each wiring route in question, and for calculating a transfer rate threshold required of each wiring route in question from the estimated delay and the wire length estimated by the wire-length estimating unit, the wiring layer assigning unit 17 for selecting wiring layers whose lowest transfer rates calculated by the transfer rate and repeater-to-repeater distance calculating unit 12 do not exceed the transfer rate threshold calculated by the transfer rate calculating unit 16 from among the plurality of wiring layers, and for assigning a wiring layer having the highest transfer rate among the selected wiring layers to each wiring route in question, the repeater inserting unit 18 for determining a repeater-to-repeater distance which minimizes the transfer rate of a wiring layer which is assigned to each wiring route whose wire length is equal to or longer than the wire length threshold by the wiring layer assigning unit 17 by using a relationship between the lowest transfer rate and the corresponding repeater-to-repeater distance, which is obtained by the transfer rate and repeater-to-repeater distance calculating unit 12, and for arranging one or more repeaters at one or more positions defined by the repeater-to-repeater distance on each wiring route in question, and the wiring processing unit 19 for performing automatic wiring on both wiring layers, which are assigned to wiring routes whose wire lengths are equal to or longer than the wire length threshold by the wiring layer assigning unit 17, and wiring routes whose wire lengths are determined to be shorter than the wire length threshold by the wire-length determining unit 15. Therefore, the automatic-arrangement-wiring apparatus can carry out the design of a semiconductor integrated circuit having appropriate timings by carrying out automatic arrangement wiring only one time and can carry out of assignment of available wiring layers efficiently at the arrangement stage and afterward in consideration of the time constants of the wiring layers and wiring resources.

In accordance with above-mentioned embodiment, when acquiring the relationship between the repeater-to-repeater distance and the transfer rate for each of the plurality of wiring layers, the transfer rate and repeater-to-repeater distance determining unit 12 can provide an amount of displacement which serves as an arrangement margin from ideal positions which are determined beforehand in consideration of the fact that repeaters cannot be actually arranged at the ideal positions, respectively. As a result, when actually arranging repeaters and it is impossible to arrange them at the ideal positions, respectively, the positions where they are to be arranged can be adjusted according to this amount of displacement.

For a certain wiring route to which a wiring layer is assigned, even if it is determined that the transfer rate is the lowest when the repeater-to-repeater distance is 1.3 mm, there is a case where repeaters cannot be arranged at the ideal positions specified by the repeater-to-repeater distance in terms of the arrangement space. In this case, the transfer rate and repeater-to-repeater distance determining unit 12 receives a user-specified amount of displacement via the graphic display device 2 or the like, and adds the user-specified amount of displacement inputted by the user to the above-mentioned repeater-to-repeater distance.

For example, when the repeater-to-repeater distance is 1.3 mm and repeaters can be arranged at positions which are distant from the ideal positions which minimize the transfer rate by 0.1 mm, the transfer rate and repeater-to-repeater distance determining unit 12 adds 0.1 mm of amount of displacement specified by the user to the above-mentioned repeater-to-repeater distance to generate the repeater-to-repeater distance of 1.4 mm.

In this case, since the propagation delay increases by only a time corresponding to the increase in the repeater-to-repeater distance from the ideal one, the automatic-arrangement-wiring apparatus selects a wiring layer having a shorter transfer rate according to the increase in the repeater-to-repeater distance from the ideal one. For example, the wire-length estimating unit 14 estimates the wire length of each of the plurality of wiring routes again in consideration of the amount of displacement from the ideal positions, or the wiring layer assigning unit 17 can change the assignment of a wiring layer to each of the plurality of wiring routes.

When determining the lowest transfer rate for each of the plurality of wiring layers having different time constants, the transfer rate and repeater-to-repeater distance determining unit 12 can determine whether or not to acquire the lowest transfer rate in consideration of cell areas, power consumption, wiring resources, etc., and can omit the acquiring process when determining that it is not unnecessary to acquire the lowest transfer rate.

As a result, the number of wiring layers which are a target of assignment by the wiring layer assigning unit 17 decreases, and a data area for data about unnecessary wiring layers is not secured in a memory, such as the hard disk drive unit 11. Therefore, the automatic-arrangement-wiring apparatus can complete the assignment processing more quickly. For example, since the FINE wiring layer (1Pitch gap) and WIDE wiring layer have much the same transfer rates which exceed 0.15 ps/μm, the assignment processing about the FINE wiring layer (1Pitch gap) having a little longer transfer rate than the WIDE wiring layer can be omitted. Thus, the assignment processing about wiring layers having similar transfer rates can be omitted.

For each wiring route whose wire length estimated by the wire-length estimating unit 14 is shorter than the wire length threshold specified by the user, the transfer rate and repeater-to-repeater distance determining unit 12 can determine a repeater-to-repeater distance which provides the lowest transfer rate for a wiring layer with a large time constant and the largest number of resources, and the repeater inserting unit 18 and wiring processing unit 19 can carry out wiring processing while inserting repeaters at fixed intervals of the determined repeater-to-repeater distance.

For example, the wire-length determining unit 15 determines whether each wiring route whose wire length is shorter than the wire length threshold specified by the user has a wire length which exceeds the above-mentioned repeater-to-repeater distance. The repeater inserting unit 18 and wiring processing unit 19 then performs wiring processing on a wiring route which is determined to have a wire length which exceeds the above-mentioned repeater-to-repeater distance while inserting repeaters at fixed intervals of the determined repeater-to-repeater distance.

In a variant of above-mentioned embodiment, when assigning a wiring layer to each wiring route whose wire length is equal to or longer than the wire length threshold specified by the user, the wiring layer assigning unit 17 does not necessarily assign a wiring layer having the highest transfer rate which is selected from wiring layers whose lowest transfer rates do not exceed the transfer rate threshold. the wiring layer assigning unit 17 can carry out the assignment of a wiring layer to each wiring route whose wire length is equal to or longer than the wire length threshold specified by the user in consideration of the proportion of already-assigned wiring layers to the total layout so that no deviation occurs in the assignment of wiring layers. As a result, the wire-to-wire coupling capacitance can be reduced and the power consumption can be reduced.

To be more specific, the wiring layer assigning unit 17 assigns a wiring layer having the highest transfer rate which is selected from wiring layers whose lowest transfer rates do not exceed the transfer rate threshold to each wiring route whose wire length is equal to or longer than the wire length threshold specified by the user first, as mentioned above, completes the assignment for all the wiring routes, and, after that, carries out a process of modifying the assignment of a wiring layer to each wiring route whose wire length is equal to or longer than the wire length threshold specified by the user according to the congestion degree of wiring. At this time, a restriction of assigning a wiring layer having a transfer rate shorter than that of the wiring layer assigned first, and not assigning a wiring layer having a transfer rate longer than that of the wiring layer assigned first is provided in advance. Thus, by assigning a wiring layer having a shorter transfer rate to each wiring route whose wire length is equal to or longer than the wire length threshold specified by the user if necessary, the wiring layer assigning unit 17 can carry out the assignment of wiring layers according to the congestion degree of wiring while maintaining the fundamental layout acquired by the first assignment of a wiring layer to each wiring route whose wire length is equal to or longer than the wire length threshold specified by the user according to the lowest transfer rates of the plurality of wiring layers.

Many widely different embodiments of the present invention may be constructed without departing from the spirit and scope of the present invention. It should be understood that the present invention is not limited to the specific embodiments described in the specification, except as defined in the appended claims.

What is claimed is:

1. An automatic-arrangement-wiring apparatus comprising:
a transfer rate and repeater-to-repeater distance calculating unit for calculating a lowest transfer rate and a corresponding repeater-to-repeater distance based on a relationship between a repeater-to-repeater distance and a transfer rate for each of a plurality of wiring layers having different time constants;
an arrangement processing unit for carrying out automatic arrangement of cells of an integrated circuit which is a target of layout based on a netlist;
a wire-length estimating unit for estimating a wire length of each of wiring routes which are disposed among the automatically-arranged cells based on arrangement results obtained by said arrangement processing unit;
a wire-length determining unit for determining whether or not the wire length of each of the wiring routes estimated by said wire-length estimating unit is equal to or longer than a wire length threshold which provides a permissible delay;
a transfer rate calculating unit for estimating a propagation delay which occurs in each wiring route whose wire length is equal to or longer than said threshold based on a timing limit provided to each wiring route in question, and for calculating a transfer rate threshold required of each wiring route in question from the estimated delay and the wire length estimated by said wire-length estimating unit;
a wiring layer assigning unit for selecting wiring layers whose lowest transfer rates calculated by said transfer rate and repeater-to-repeater distance calculating unit do not exceed the transfer rate threshold calculated by said transfer rate calculating unit from among the plurality of wiring layers, and for assigning a wiring layer having a highest transfer rate among the selected wiring layers to each wiring route in question;
a repeater inserting unit for determining a repeater-to-repeater distance which minimizes the transfer rate of a wiring layer which is assigned to each wiring route whose wire length is equal to or longer than said wire length threshold by said wiring layer assigning unit by using a relationship between the lowest transfer rate and the corresponding repeater-to-repeater distance, which is obtained by said transfer rate and repeater-to-repeater distance calculating unit, and for arranging one or more repeaters at one or more positions defined by said repeater-to-repeater distance on each wiring route in question; and
a wiring processing unit for performing automatic wiring on both wiring layers, which are assigned to wiring routes whose wire lengths are equal to or longer than said wire length threshold by said wiring layer assigning unit, and wiring routes whose wire lengths are determined to be shorter than said wire length threshold by said wire-length determining unit.

2. The automatic-arrangement-wiring apparatus according to claim 1, wherein said wiring processing unit performs the automatic wiring sequentially on the wiring layers in increasing order of their transfer rates.

3. The automatic-arrangement-wiring apparatus according to claim 1, wherein said transfer rate and repeater-to-repeater distance calculating unit receives an amount of displacement, which is an arrangement margin, from each of said one or more positions defined by said repeater-to-repeater distance which maximizes the transfer rate of the wiring layer assigned to said each wiring route in question by said wiring layer assigning unit, and said repeater inserting unit arranges the one or more repeaters at one or more modified positions which are obtained by adding said amount of displacement to said one or more positions.

4. The automatic-arrangement-wiring apparatus according to claim 1, wherein when calculating the lowest transfer rate for each of wiring layers having similar transfer rates, said transfer rate and repeater-to-repeater distance calculating unit acquires the lowest transfer rate for only one of said wiring layers.

5. The automatic-arrangement-wiring apparatus according to claim 1, wherein even for a wiring route whose wire length is determined to be shorter than said wire length threshold by said wire-length determining unit, said repeater inserting unit arranges repeaters at intervals of a repeater-to-repeater distance which provides a lowest transfer rate determined by said transfer rate and repeater-to-repeater distance calculating unit.

6. The automatic-arrangement-wiring apparatus according to claim 1, wherein after completing the assignment of a wiring layer to each of the wiring routes according to the lowest transfer rates of the plurality of wiring layers, said wiring layer assigning unit makes a correction to the assignment of said wiring layer to each of the wiring routes by assigning another wiring layer having a shorter transfer rate than said wiring layer to each of the wiring routes according to congestion degree of wiring.

7. A program which causes a computer to operate as:
a transfer rate and repeater-to-repeater distance calculating unit for calculating a lowest transfer rate and a corresponding repeater-to-repeater distance based on a relationship between a repeater-to-repeater distance and a transfer rate for each of a plurality of wiring layers having different time constants;
an arrangement processing unit for carrying out automatic arrangement of cells of an integrated circuit which is a target of layout based on a netlist;
a wire-length estimating unit for estimating a wire length of each of wiring routes which are disposed among the automatically-arranged cells based on arrangement results obtained by said arrangement processing unit;
a wire-length determining unit for determining whether or not the wire length of each of the wiring routes estimated by said wire-length estimating unit is equal to or longer than a wire length threshold which provides a permissible delay;
a transfer rate calculating unit for estimating a propagation delay which occurs in each wiring route whose wire length is equal to or longer than said threshold based on a timing limit provided to each wiring route in question, and for calculating a transfer rate threshold required of each wiring route in question from the estimated delay and the wire length estimated by said wire-length estimating unit;
a wiring layer assigning unit for selecting wiring layers whose lowest transfer rates calculated by said transfer rate and repeater-to-repeater distance calculating unit do not exceed the transfer rate threshold calculated by said transfer rate calculating unit from among the plurality of wiring layers, and for assigning a wiring layer having a highest transfer rate among the selected wiring layers to each wiring route in question;
a repeater inserting unit for determining a repeater-to-repeater distance which minimizes the transfer rate of a wiring layer which is assigned to each wiring route whose wire length is equal to or longer than said wire length threshold by said wiring layer assigning unit by using a relationship between the lowest transfer rate and the corresponding repeater-to-repeater distance, which is obtained by said transfer rate and repeater-to-repeater distance calculating unit, and for arranging one or more repeaters at one or more positions defined by said repeater-to-repeater distance on each wiring route in question; and
a wiring processing unit for performing automatic wiring on both wiring layers, which are assigned to wiring routes whose wire lengths are equal to or longer than said wire length threshold by said wiring layer assigning unit, and wiring routes whose wire lengths are determined to be shorter than said wire length threshold by said wire-length determining unit.
